(19) United States
(12) Patent Application Publication
(10) Pub. No.: US 2025/0226373 A1
(43) Pub. Date: Jul. 10, 2025

(54) PHOTOELECTRIC DEVICE, OPTICAL TRANSCEIVER, AND METHOD OF OPERATING PHOTOELECTRIC DEVICE

(71) Applicant: TAIWAN SEMICONDUCTOR MANUFACTURING COMPANY LTD., HSINCHU (TW)

(72) Inventors: YOU-CHENG LU, TAINAN CITY (TW); STEFAN RUSU, SUNNYVALE, CA (US); LAN-CHOU CHO, HSINCHU CITY (TW); MING YANG JUNG, KAOHSIUNG CITY (TW); TAI-CHUN HUANG, NEW TAIPEI CITY (TW)

(21) Appl. No.: 18/403,779

(22) Filed: Jan. 4, 2024

(51) Int. Cl. H01L 25/18; G02B 6/42; H01L 23/538

(52) U.S. Cl. CPC H01L 25/18; G02B 6/4246; H01L 23/5385

(57) ABSTRACT

A photoelectric device, an optical transceiver, and a method of operating the photoelectric device are provided. The photoelectric device include a first die and a second die. The first die has a first back side. The second die is disposed over the first die. The second die has a second back side bonded to the first back side. The second die includes an optical circuitry and an electrical circuitry. The optical circuitry is configured to generate or process a first optical signal. The electrical circuitry is electrically coupled to the first die, and is configured to control an operation of the optical circuitry by a first electrical signal inputted into the first die or to provide a second electrical signal to the first die in response to the first optical signal.

### BACKGROUND

Electro-optical modules can be used to convert electrical signals into optical signals and vice versa. Many different types of electro-optical modules are presently manufactured. These modules have many applications, particularly within data-communications applications where electrical signals are carried by optical fibers.

Different types of electro-optical modules can be used to perform different functions. Receive modules and transmit modules, for example, are used to perform portions of an electro-optical conversion. More particularly, receive modules convert optical signals into electrical signals as part of a receiving function. Transmit modules convert electrical signals into optical signals as part of a transmitting function. Transceiver modules can be used to perform the electro-optical conversion for both receiving and transmitting processes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic cross-sectional view of a photoelectric device in accordance with some embodiments of the present disclosure.

FIG. 2 is a schematic view of one or more optical fibers attaching an optical die to other devices in accordance with some embodiments of the present disclosure.

FIG. 3 is a schematic cross-sectional view of an electronic die and an optical die of the photoelectric device illustrated in FIG. 1.

FIG. 4 is a circuit diagram of a transmission circuit in accordance with some embodiments of the present disclosure.

FIG. 5 is a circuit diagram of an optical transimpedance amplifier in accordance with some embodiments of the present disclosure.

FIG. 6 is an enlarged view of an area A of FIG. 3.

FIG. 7 is a schematic top view of a part of an electronic die in accordance with some embodiments of the present disclosure.

FIG. 8 is a schematic perspective view of a part of an optical die and optical fibers.

FIG. 9 is a schematic diagram of an optical circuitry of a photoelectric device that serves as an optical transmitter in accordance with some embodiments of the present disclosure.

FIG. 10 is a schematic diagram of an optical circuitry of a photoelectric device that serves as an optical transmitter in accordance with some embodiments of the present disclosure.

FIG. 11 is a schematic diagram of a two-dimensional grating coupler in accordance with some embodiments of the present disclosure.

FIG. 12 is a schematic diagram of a splitter network in accordance with some embodiments of the present disclosure.

FIG. 13 is a schematic diagram of a one-dimensional grating coupler in accordance with some embodiments of the present disclosure.

FIG. 14 is a schematic diagram of an optical circuitry of a photoelectric device that serves as an optical receiver in accordance with some embodiments of the present disclosure.

FIG. 15 is a schematic cross-sectional view of an electronic die and an optical die of the photoelectric device illustrated in FIG. 1.

FIG. 16 is a schematic cross-sectional view of an electronic die and an optical die of the photoelectric device illustrated in FIG. 1.

FIG. 17 is a schematic diagram of an edge coupler in accordance with some embodiments of the present disclosure.

FIG. 18 is a schematic diagram of an edge coupler in accordance with some embodiments of the present disclosure.

FIG. 19 is a schematic diagram of an edge coupler in accordance with some embodiments of the present disclosure.

FIG. 20 is a schematic perspective view of a part of an optical die in accordance with some embodiments of the present disclosure.

FIG. 21 is a schematic side view of a part of an optical die in accordance with some embodiments of the present disclosure.

FIG. 22 is a schematic top view of a part of an optical die and optical fibers in accordance with some embodiments of the present disclosure.

FIG. 23 is a schematic diagram of an optical transceiver in accordance with some embodiments of the present disclosure.

FIG. 24 is a schematic block diagram of a part of an optical transceiver in accordance with some embodiments of the present disclosure.

FIG. 25 is a schematic diagram of an optical transceiver in accordance with some embodiments of the present disclosure.

FIG. 26 is a schematic block diagram of a part of an optical transceiver in accordance with some embodiments of the present disclosure.

FIG. 27 is a flowchart of a method for operating a photoelectric device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another end point or between two endpoints. All ranges disclosed herein are inclusive of the endpoints, unless specified otherwise.

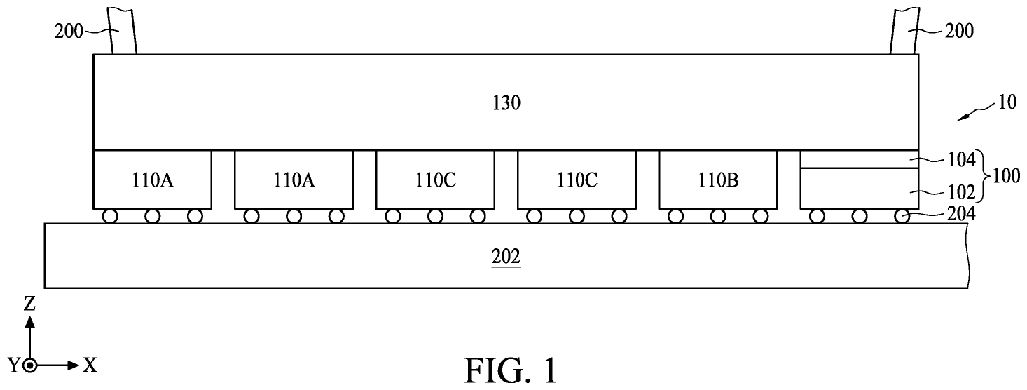

FIG. 1 is a schematic cross-sectional view of a photoelectric device in accordance with some embodiments of the present disclosure. Referring to FIG. 1, the photoelectric device 10 includes a plurality of electronic dies 110A, 110B and 110C and an optical die 130. The electronic dies 110A, 110B and 110C may be laterally separated from each other, and the optical die 130 is stacked over the electronic dies 110. The electronic dies 110A, 110B and 110C may include different functional circuitries. For example, the electronic die 110A includes processing logic circuitry, the electronic die 110B includes a high-speed filter, and the electronic die 110C includes communication drive circuitry such as a transmission drive circuit, a reception drive circuit, or transceiver circuitry including integrated transmission and reception drive circuits.

The electronic dies 110A may be arranged to function with one another to control operations of the photoelectric device 10. In some embodiments, the high-speed filter is adapted to minimize noise injection. The high-speed filter may be implemented by, for example, an RC filter. The RC filter may include a trench resistor to minimize a footprint of the electronic die 110B.

In some embodiments, the communication drive circuitry is configured to drive the transmission or reception circuitry in the optical die 130. In some circumstances, the electronic dies 110A to 110C have a relatively short service life compared to a service life of the optical die 130, and the communication drive circuitry is used more frequently than the processing logic circuitry and the high-speed filter, so that the service life of the communication drive circuitry expires earlier. Such short service life of the communication drive circuitry may pose challenges to a service life and reliability of the overall device. The photoelectric device 10 may thus include multiple electronic dies 110C including same or similar communication drive circuitries in order to extend an overall service life of the photoelectric device 10.

In some embodiments, the processing logic circuitry is configured to activate one of the electronic dies 110C and deactivate the other electronic dies 110C at a particular point in time. The processing logic circuitry may perform a monitoring operation on the activated electronic die 110C to monitor a status of the activated electronic die 110C. For example, the processing logic circuitry is configured to evaluate the status of the activated electronic die 110C and determine whether the activated electronic die 110C has a normal operation status or is non-responsive. The non-responsive status indicates that the activated electronic die 110C is no longer functional. The electronic die 110C that is no longer functional is considered as a failed die. The deactivated electronic dies 110C serve as backup electronic dies 110C that can be used to replace the failed die during normal operation. In response to the non-responsive status, the processing logic circuitry may deactivate the activated electronic die 110C, and activate one of the backup electronic dies 110C. In some embodiments, the processing logic circuitry may include a memory for storing information related to the electronic dies 110C. Whether the electronic die 110C to be activated is the failed die may be included in the information. The processing logic circuitry controls the operation of the electronic dies 110C in accordance with the information stored in the memory.

Still referring to FIG. 1, the electronic dies 110A to 110C may have substantially a same thickness. Furthermore, the electronic dies 110A to 110C have a relatively small footprint compared to a footprint of the optical die 130. In order to improve uniformity and planarization in an underlying layer of the photoelectric device 10 (i.e., a layer below the electronic dies 110A to 110C), the photoelectric device 10 may further include one or more dummy dies 100. In some embodiments, a thickness of the dummy die 100 is designed to be equal to the thickness of the electronic dies 110A to 110C. The dummy dies 100 do not perform any electrical or optical functions in the operation of the photoelectric device 10, and are not supplied with power. The dummy dies 100 may be substantially free of any active devices, functional circuits, or the like. For example, the dummy dies 100 may include a substrate 102 (e.g., a bulk silicon substrate) and a bonding layer 104 disposed in a surface of the substrate 102. The bonding layer 104 may be used to bond the dummy die 100 to the optical die 130 using a fusion bonding process, for example.

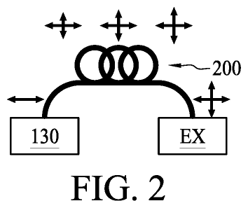

In some embodiments, as shown in FIG. 2, one or more optical fibers 200 are attached to the optical die 130, thus enabling the photoelectric device 10 to have optical communication with other devices EX. Due to long distances of signal propagation over the optical fiber 200, optical signals are interrupted, suggesting that both transverse electric (TE) mode and transverse magnetic (TM) mode optical signals exist simultaneously, wherein the TE-mode optical signals and the TM-mode optical signals are linear polarized signals orthogonal to each other. More particularly, the polarized optical signals in either the TE mode or the TM mode may change to a combined TE and TM mode during propagation in the optical fiber 200. The optical signals in the combined TE and TM mode from the optical fibers 200 may be transformed back to the TE mode or the TM mode in the optical die 130. Hence, the optical fibers 200 may be a polarization-maintaining fiber (PMF) able to maintain a TE-to-TM ratio during propagation. The polarization-maintaining fiber may ensure that an intensity loss during conversion of the combined TE and TM mode to the TE mode or the TM mode is low (i.e., intensity loss of about 3 dB), providing a reliable mode transition in the optical fiber 200.

The photoelectric device 10 can be either an optical transmitter or an optical receiver, and can therefore transmit optical signals to or receive optical signals from the optical fibers 200. The photoelectric device 10 may be mounted to a circuit board 202 using connectors 204 (such as solder balls, controlled collapse chip connections (C4) bumps or micro-C4 bumps) or other suitable configurations, such as copper pillars.

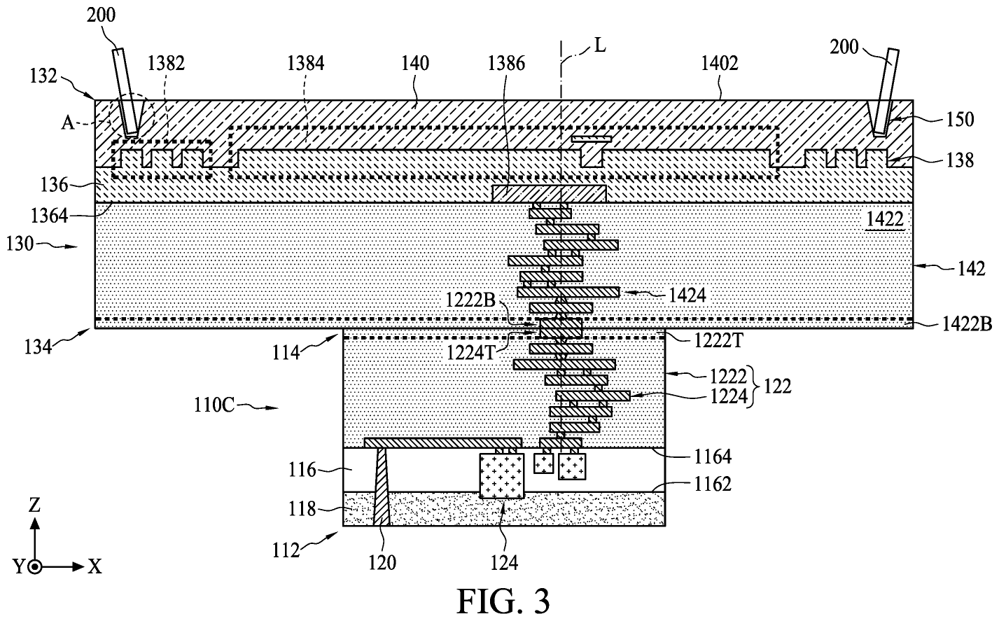

FIG. 3 is a schematic cross-sectional view of one of the electronic dies 110C and the optical die 130 of the photoelectric device 10 illustrated in FIG. 1. Referring to FIG. 3, the electronic die 110C provides conductive pathways for routing electrical signals to and/or from the optical die 130. The electronic die 110C may also exchange electrical signals with the optical die 130.

In some embodiments where the photoelectric device 10 serves as an optical transmitter, the electrical signals are provided by a circuitry external to the electronic die 110C. For example, the electrical signals are provided by the electronic die 110A. The electronic die 110C is used to receive the electrical signals from the external circuitry and to interact with the optical die 130, wherein the electrical signals may be used for generating and/or processing optical signals. In some embodiments where the photoelectric device 10 serves as an optical receiver, the electrical signals are provided by the optical die 130. The electronic die 110C is used to receive the electrical signals from the optical die 130 and to interact with the external circuitry, wherein the electrical signals may represent intensities of the optical signals within the optical die 130.

The electronic die 110C has a front side 112 and a back side 114 that is opposite to the front side 112. The electronic die 110C receives the electrical signals from or transmits the electrical signals to the external circuitry via the front side 112 of the electronic die 110C.

The optical die 130 can transmit, receive, convert, modulate, demodulate, or otherwise process the optical signals. In some embodiments where the photoelectric device 10 serves as the optical transmitter, the optical die 130 is configured to convert the electrical signals from the electronic die 110C to the optical signals, process the optical signals in response to the electrical signals from the electronic die 110C, or both. The optical die 130 may be further configured to transmit the optical signals out of the optical die 130 and electrically communicable with the electronic die 110C. In some embodiments where the photoelectric device 10 serves as the optical receiver, the optical die 130 converts the optical signals to the electrical signals. An intensity/power of received optical signals may be measured by the optical receiver. The electrical signals representing such measured intensity/power value are then transmitted to the electronic die 110C.

The optical die 130 has a front side 132 and a back side 134 that is opposite to the front side 132. The optical signals may enter and/or exit the photoelectric device 10 through the front side 132 of the optical die 130. The optical die 130 is bonded to the electronic die 110C through, for instance, hybrid bonding, and the back side 134 of the optical die 130 is mounted on the back side 114 of the electronic die 110C, thereby forming a back-to-back arrangement.

The electronic die 110C may include a semiconductor substrate 116, a passivation layer 118, a conductive pillar 120, and an interconnect structure 122. The front side 112 of the electronic die 110C may refer to a side including the conductive pillar 120 utilized to transmit the electrical signals to or receive the electrical signals from the external circuitry.

The passivation layer 118 is disposed on a first surface 1162 of the semiconductor substrate 116. The passivation layer 118 may include dielectric material such as oxide or polymer (e.g., polyimide). The conductive pillar 120 may be part of a transmission path of the electrical signals. In addition, the conductive pillar 120 serves as an input/output port of the electronic die 110C. The conductive pillar 120 extends through the passivation layer 118 and into the semiconductor substrate 116. In some embodiments, the conductive pillar 120 penetrates through the semiconductor substrate 116 and the passivation layer 118. In some embodiments, the conductive pillar 120 is formed from a conductive material including copper, aluminum, tungsten, combinations thereof, or the like.

The interconnect structure 122 is adapted to connect the electronic die 110C to the optical die 130. The interconnect structure 122 includes a dielectric stack 1222 and a plurality of conductive features 1224 disposed in the dielectric stack 1222. In some embodiments, the dielectric stack 1222 is disposed on a second surface 1164 of the semiconductor substrate 116 and includes a plurality of dielectric films formed from one or more dielectric materials. The dielectric films may include low-k dielectric materials. The conductive features 1224 may be lines and vias, and may be formed by a damascene process, e.g., a dual damascene process, a single damascene process, or the like. A material of the conductive features 1224 may be same as or different from a material of the conductive pillar 120.

One or more electronic components 124 may be formed in and/or on the semiconductor substrate 116. In some embodiments, the electronic components 124 include passive and/or active components that are arranged to operate with one another to provide desired functionality. For example, the passive components may include resistors, capacitors, inductors, or a combination thereof, and the active components may include transistors, diodes, or the like. The passivation layer 118 may cover the electronic components 124 exposed through or disposed on the semiconductor substrate 116. The conductive pillar 120 may be laterally separated from the electronic components 124 and electrically connected to the electronic components 124 by the interconnect structure 122.

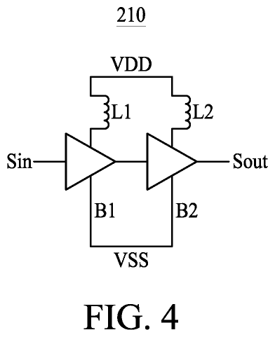

The interconnect structure 122 electrically connects to the electronic components 124 to form functional circuits within the electronic die 110C. The functional circuits control high-frequency signaling of the optical die 130. In embodiments where the photoelectric device 10 serves as the optical transmitter, the functional circuits include a transmission circuit. FIG. 4 is a circuit diagram of a transmission circuit in accordance with some embodiments of the present disclosure. With reference to FIG. 4, the transmission circuit 210 receives an input (voltage) signal Sin and then generates an output (voltage) signal Sout. The transmission circuit 210 may be adapted to high frequency and configured to drive one or more optical features (such as micro-ring modulators) in the optical die 130. The transmission circuit 210 include a pair of buffers B1 and B2 and a pair of inductors L1 and L2. The buffers B1 and B2 are connected in series. More particularly, an output terminal of the buffer B1 is connected to an input terminal of the buffer B2. An input terminal of the buffer B1 receives the input (voltage) signal Sin, and an output terminal of the buffer B2 provides the output (voltage) signal Sout. The inductors L1 and L2 are coupled to the buffers B1 and B2, respectively, between the power supply voltage level VDD and reference level VSS.

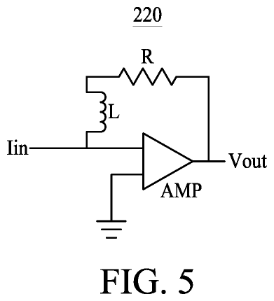

In embodiments where the photoelectric device 10 serves as the optical receiver, the functional circuits may include a reception circuit. In some embodiments, the reception circuit includes an optical transimpedance amplifier (TIA). The optical transimpedance amplifier is, for example, a current-to-voltage converter. FIG. 5 is a circuit diagram of the optical transimpedance amplifier in accordance with some embodiments of the present disclosure. With reference to FIG. 5, the optical transimpedance amplifier 220 receives an input current signal lin and generates an output voltage signal Vout. The optical transimpedance amplifier 220 may be adapted to high frequency and may include an operational amplifier AMP, an inductor L, and a resistor R. A non-invert input terminal of the operational amplifier AMP is grounded. The inductor L and the resistor R are coupled between an invert input terminal and an output terminal of the operational amplifier AMP. More particularly, a first end of the inductor L is connected to the invert input terminal of the operational amplifier AMP, a second end of the inductor L is connected to a first end of the resistor R, and a second end of the resistor R is connected to the output terminal of the operational amplifier AMP.

Referring back to FIG. 3, the optical die 130 may include a semiconductor layer 136, an optical circuitry 138, an insulating layer 140, and an electrical circuitry 142. The front side 132 of the optical die 130 may refer to a side including the optical circuitry 138. The semiconductor layer 136 may include an elementary semiconductor, such as silicon (Si) or germanium (Ge) in a crystalline structure; a component semiconductor, such as silicon germanium (SiGe), silicon carbide (SiC), gallium arsenic (GaAs), gallium phosphide (GaP), indium phosphide (InP), indium arsenide (InAs), or indium antimonide (InSb); or a combination thereof.

The optical circuitry 138 is disposed in the semiconductor layer 136. The optical circuitry 138 may include input/output optical couplers (such as grating couplers) 1382 configured to interface with the optical fibers 200, waveguides 1384, and a plurality of optical features 1386 which may perform one or more functions relating to receiving optical signals from the waveguides 1384. Some of the input/output optical couplers 1382 are used to transmit optical signals between the waveguides 1384 and the optical fibers 200. Due to very large differences in dimensions of the waveguide 1384 and the optical fiber 200, direct coupling would incur tremendous light loss. In some embodiments, some of the input/output optical couplers 1382 are disposed over the semiconductor layer 136 and used to transmit the optical signals between the waveguides 1384.

The optical features may be functional in response to the electronic signals from the electronic die 110C. The optical features may include radiation generators (e.g., lasers or light-emitting diodes), splitters, modulators, processors, amplifiers, multiplexers, optical sensing/detection components (e.g., photodiodes), or the like.

The insulating layer 140 may surround and cover the optical circuitry 138. The insulating layer 140 may be made of glass or transmissive media such as optical polymers, dielectric material including silicon dioxide, an ultra-low-k dielectric material, a low-k dielectric material (e.g., SiCO), or the like. The insulating layer 140 may have an index of refraction less than that of the semiconductor layer 136, resulting in optical confinement in the optical circuitry 138. At least some input/output optical couplers and waveguides may be disposed in the insulating layer 140; the input/output optical couplers and the waveguides are vertically stacked on top of one another, and laterally overlapping with neighboring input/output optical couplers or waveguides.

The electrical circuitry 142 may include a dielectric stack 1422 and a plurality of conductive features 1424. The dielectric stack 1422 is disposed on a back surface 1364 of the semiconductor layer 136, and the conductive features 1424 are surrounded by the dielectric stack 1422. The dielectric stack 1422 may be substantially similar to and formed in a same manner as the dielectric stack 1222 of the electronic die 110C. The conductive features 1424 may be any type of conductive structure and may include, for example, conductive lines, conductive vias, and conductive contacts. The conductive vias may connect adjacent conductive lines along a Z direction.

In some embodiments, topmost conductive features 1224T of the electronic die 110C and bottommost conductive features 1222B of the optical die 130 serve as bonding pads of the electronic die 110C and the optical die 130, respectively. In addition, a topmost dielectric film 1222T of the dielectric stack 1222 of the electronic die 110C and a bottommost dielectric film 1422B of the dielectric stack 1422 of the optical die 130 serve as bonding agents for hybrid bonding. The electronic die 110C and the optical die 130 are bonded backside to backside using the topmost conductive features 1224T, the topmost dielectric film 1222T, the bottommost conductive features 1222B, and the bottommost dielectric film 1422B. More particularly, the electronic die 110C and the optical die 130 are bonded by hybrid bonding the topmost conductive features 1224T to the bottommost conductive features 1222B and the topmost dielectric film 1222T to the bottommost dielectric film 1422B.

After the hybrid bonding, the topmost conductive features 1224T of the electronic die 110C may direct contact and electrically connect to the bottommost conductive features 1222B of the optical die 130. The optical features 1386 may overlap one or more electronic components 124 from a top-view perspective. The optical features 1386 may further overlap the conductive features 1224 and 1424 from a top-view perspective. As shown in FIG. 3, the optical features 1386, the electronic components 124, and the conductive features 1224 and 1424 are designed to be arranged along a line L extending in the Z direction.

The backside-to-backside arrangement, the configuration allowing the input and/or output of the electrical signal through the front side 112 of the electronic die 110C, and the configuration allowing the input and/or output of the optical signals through the front side 132 of the optical die 130 all allow reduction of a transmission distance of the electrical signals between the optical features and an I/O port of the electronic die 110, thereby avoiding or mitigating loss of signal integrity at high transmission speeds.

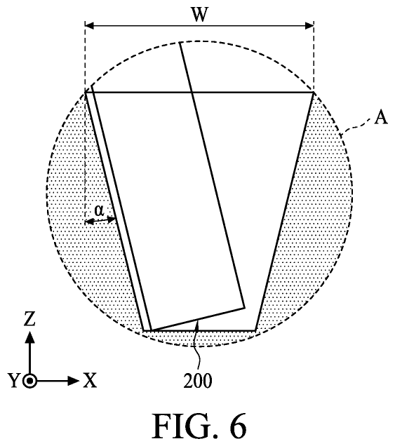

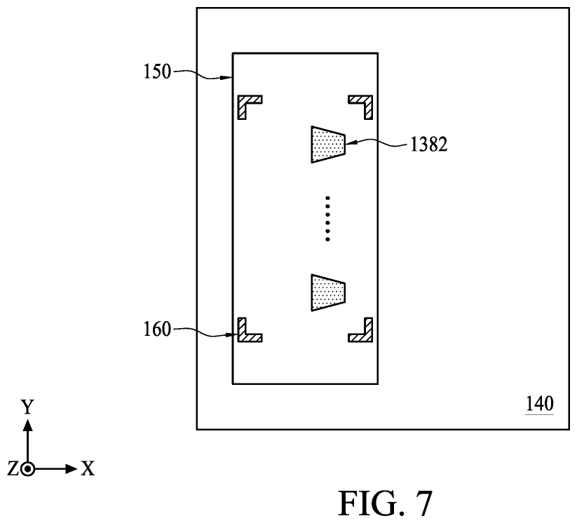

Still referring to FIG. 3, the optical die 130 may further include one or more coupler recesses 150 disposed over the input/output optical couplers 1382. The coupler recesses 150 are formed in the insulating layer 140 and adapted to direct the optical signals from the optical fibers 200 into the optical die 130. Specifically, the coupler recesses 150 extend downward from an upper surface 1402 of the insulating layer 140 into an interior of the insulating layer 140. FIG. 6 is an enlarged view of an area A of FIG. 3, and FIG. 7 is a schematic top view of a part of the optical die 130 in accordance with some embodiments of the present disclosure. Referring to FIGS. 6 and 7, the coupler recess 150 may have a rectangular shape from a top-view perspective, and may have a trapezoidal shape from a cross-sectional perspective. In addition, a width W of the coupler recess 150 decreases at decreasing distances from the input/output optical coupler 1382, such that the coupler recess 150 has a tilt angle α with respect to the Z direction. The tilt angle α may be in a range of 5 degrees to 15 degrees. In one exemplary embodiment, the tilt angle α is about 8 degrees.

In some embodiments, the optical die 130 can further include a plurality of alignment marks 160 used to align positions of the optical fibers 200. The alignment marks 160 are adapted to ensure that the optical fibers 200 are placed at a desirable location and that the optical fibers 200 do not shift or rotate from their intended position and direction. The alignment marks 160 are disposed on or in the insulating layer 140 and are exposed through the coupler recess 150. In one example, the alignment marks 160 are grooves or protrusions having desired patterns formed in the insulating layer 140. The grooves may extend downward from a top surface of the insulating layer 140 into the interior of the insulating layer 140. In another example, the alignment marks 160 are formed by depositing a dielectric film having the desired pattern on the insulating layer 140. In yet another example, the alignment marks 160 are formed by depositing a dielectric material in a plurality of grooves formed in the insulating layer 140. The dielectric film and the dielectric material for the formation of the alignment marks 160 may have a color different from that of the insulating layer 140 and the semiconductor layer 136, thus facilitating recognition of the alignment marks 160 during attachment of the optical fibers 200 to the optical die 130.

The alignment marks 160 are arranged around the input/output optical coupler 1382. In some embodiments, the optical die 130 includes four alignment marks, wherein each alignment mark is disposed in proximity to a respective corner of the coupler recess 150 in the insulating layer 140. In some embodiments, the alignment marks 160 may be L-shaped alignment marks. Alternatively, the alignment marks 160 may be cross-shaped, T-shaped, or any suitable shape.

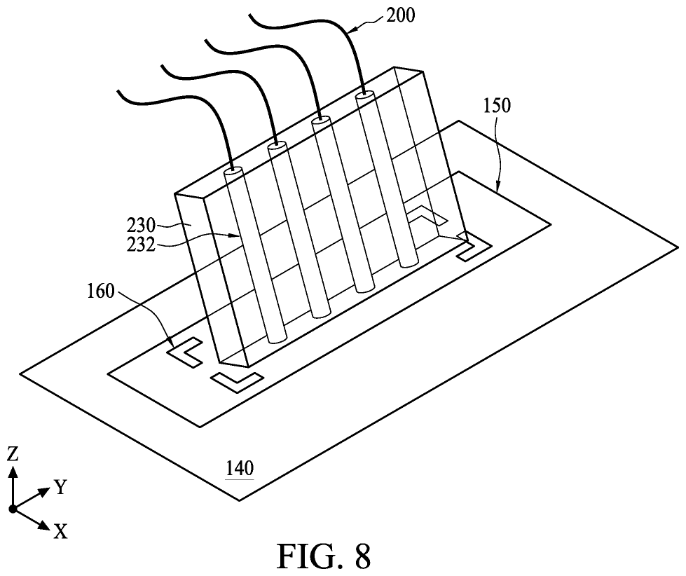

FIG. 8 is a schematic perspective view of a part of the optical die 130 and the optical fibers 200. Referring to FIG. 8, in some embodiments, the optical fibers 200 are positioned by a base 230 at one or more predetermined intervals along a Y direction. The base 230 may have a rectangular shape. The base 230 is made of, for example, a thermoplastic resin. Other materials, such as glass, ceramic material, metal, etc., can also be utilized. The base 230 may include multiple guide holes 232 to receive the optical fibers 200. In some embodiments, dimensions of the guide holes 232 are dictated by a size of the optical fibers 200. The base 230 is angularly positioned within the coupler recess 150 and aligned in an area defined by the alignment marks 160. When the optical fibers 200 are placed within the guide holes 232, centers of the optical fibers 200 are optically aligned with the input/output optical couplers 1382 (as shown in FIG. 7). The coupler recess 150 has the tilt angle α such that the base 230 disposed in the coupler recess 150 may be properly oriented with respect to the Z direction. By limiting an angle of the optical fiber 200 to approximately the tilt angle α, an efficiency of the coupler recess 150 may be improved. In some embodiments, sidewalls of the base 230 are offset from a surface of the insulating layer 140 exposed through the coupler recess 150. Alternatively, a sidewall of the base 230 may be attached to a surface of the insulating layer 140 exposed through the coupler recess 150.

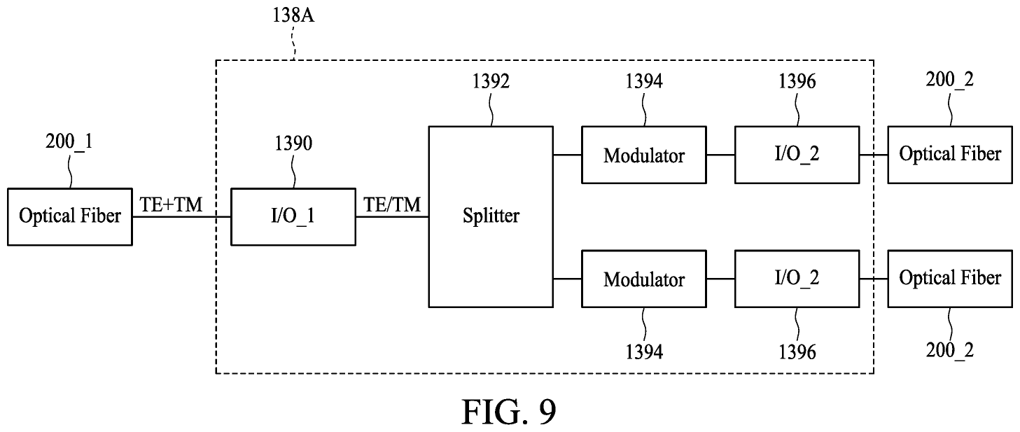

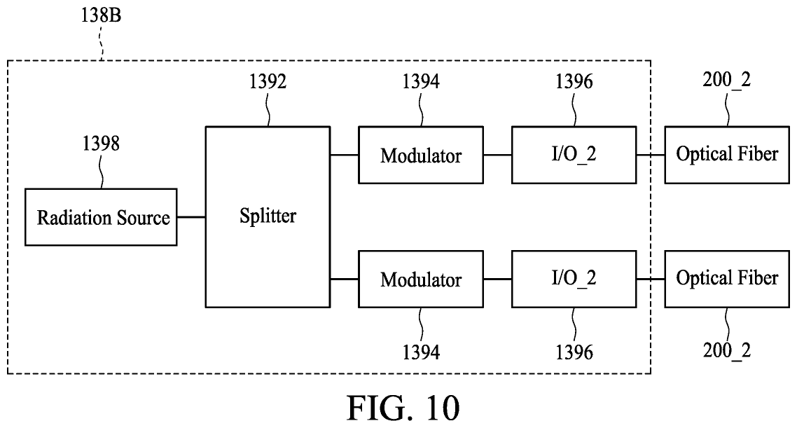

FIGS. 9 and 10 are schematic diagrams of optical circuitries of the photoelectric device 10, wherein the optical circuitries serve as the optical transmitter in accordance with some embodiments of the present disclosure. The optical circuitry 138A in FIG. 9 is adapted to process an input optical signal, while the optical circuitry 138B in FIG. 10 is adapted to generate an optical signal and process an input optical signal. With reference to FIG. 9, the optical circuitry 138A includes a first I/O coupler (I/O_1), a splitter 1392, a plurality of modulators 1394, and a plurality of second I/O couplers (I/O_2) 1396. The optical circuitry 138B in FIG. 10 is similar to the optical circuitry 138A in FIG. 9. Therefore, same reference numerals are used to refer to same or similar elements. A difference between the optical circuitries 138A and 138B is that the first I/O coupler (I/O_1) of the optical circuitry 138A is replaced with a radiation generator 1398 in the optical circuitry 138B. The radiation generator 1398 is configured to generate an optical signal to be processed and transmitted to the optical fibers 200_2.

Referring back to FIG. 9, the first input/output optical coupler 1390 is used to direct input optical signals from an optical fiber 200_1 to the splitter 1392. The input optical signals are usually in an unknown and arbitrary polarization state, such that the first input/output optical coupler 1390 may be a two-dimensional grating coupler to provide polarized optical signals in TE and TM modes from the optical fiber 200_1 to the respective splitter 1392.

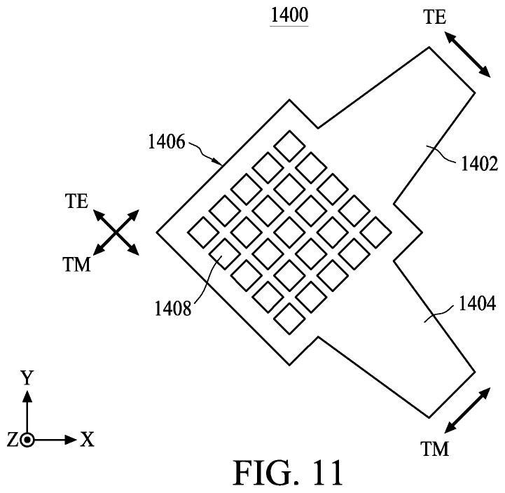

FIG. 11 is a schematic diagram of a two-dimensional grating coupler in accordance with some embodiments of the present disclosure. Referring to FIG. 11, the two-dimensional grating coupler 1400 may include a first taper structure 1402, a second taper structure 1404, and a grating structure 1406. The grating structure 1406 can be formed at an intersection of a pair of orthogonal integrated taper structures (e.g., the first taper structure 1402 and the second taper structure 1404). The grating structure 1406 includes an array of holes 1408 (or, alternatively, an array of posts (not shown)). The grating structure 1406 may be utilized to separate the TE-mode optical signal from the TM-mode optical signal. The grating structure 1406 may further be configured to transmit the TE-mode optical signal to the first taper structure 1402. In addition, the grating structure 1406 may transmit the TM-mode optical signal to the second taper structure 1404. At least one of the TE-mode and TM-mode optical signals is then transmitted to the splitter 1392 shown in FIG. 9. FIG. 9 only shows one splitter for processing either the TE-mode or TM-mode optical signal (with one of the TE-mode and TM-mode optical signals not being used, or terminated), but it should be understood that, in some embodiments, an optical circuitry for processing both the TE-mode and TM-mode optical signals may include two splitters.

The splitter 1392 includes an input port and a plurality of output ports. The input port is optically coupled to the first input/output optical coupler 1390 for receiving the TM-mode or TE-mode optical signal, and the output ports are optically coupled to the modulators 1394. The splitter 1392 is configured to split the input optical signal received at the input port and provide the split signal to the output ports. For example, the splitter 1392 shown in FIG. 9 splits the input optical signal into two output optical signals. In some embodiments, the splitter 1392 is used to divide the input optical signal equally into the output optical signals with minimum insertion loss. The output optical signal may have same spectral characteristics, but each has approximately one-half the signal power as the input optical signal. The splitter 1392 may be a Y-junction splitter, a directional coupler (DC) splitter, a Mach Zehnder interferometer (MZI), or other suitable splitter.

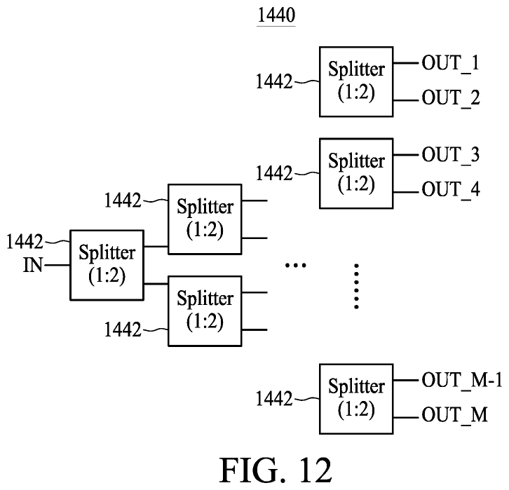

The input optical signal may be split into more than two output optical signals (e.g., 4, 8, 16, 32, etc.) by cascading stages to form a splitter network. FIG. 12 is a schematic diagram of the splitter network 1440 in accordance with some embodiments of the present disclosure. Referring to FIG. 12, the splitter network 1440 may have a split ratio of 1:M; i.e., the splitter network 1440 having one input port IN and M output ports OUT_1 to OUT_M, where M is an integer greater than one. In some embodiments, the splitter network 1440 is implemented by cascading a plurality of splitters 1442 having a splitter ratio of 1:2. The splitter network 1440 may be implemented with a number of output ports that follows a binary form 2n (2, 4, 8, 16, etc.), where n is an integer equal to or greater than one. A non-binary number of ports can be implemented by using a next larger binary dimension and terminating unused ports. The present disclosure also contemplates the use of a non-binary form. For example, a splitter network having a split ratio of 1:6 may be implemented by cascading a splitter having a splitter ratio of 1:2 and two splitters each having a splitter ratio of 1:3.

Referring back to FIG. 9, the modulators 1394 are configured to manipulate a property of the optical signals. In some embodiments, the modulators 1394 modulate an intensity and/or a phase of the optical signal from the splitter 1392 based on the electrical signal. The modulator 1394 is, for example, a micro-ring modulator (MRM) or a Mach Zehnder modulator (MZM).

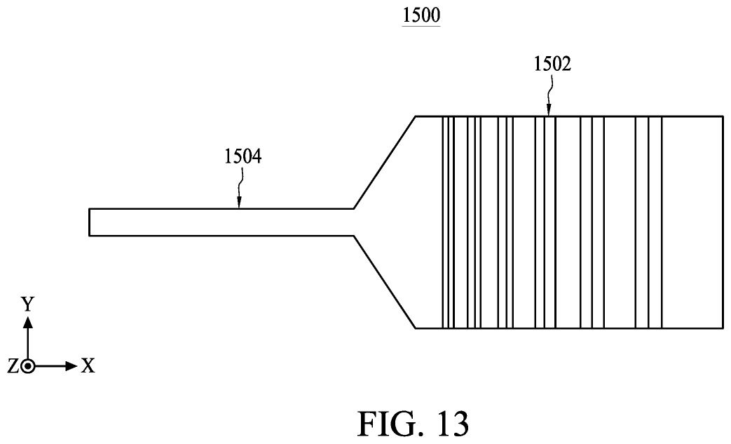

The second I/O couplers 1396 are configured to transmit the optical signals between the modulators 1394 and the optical fibers 200_2. The second I/O couplers 1396 may be one-dimensional grating couplers. FIG. 13 is a schematic diagram of the one-dimensional grating coupler in accordance with some embodiments of the present disclosure. With reference to FIG. 13, the one-dimensional grating coupler 1500 includes a grating structure 1502 and an integrated waveguide 1504. The grating structure 1502 including a pattern is utilized to scatter an optical signal received from the waveguide 1504. The pattern is determined based on a shape, a geometry, and materials of coupling gratings of the grating structure 1502, as well as on a desired operational wavelength range of the optical signal.

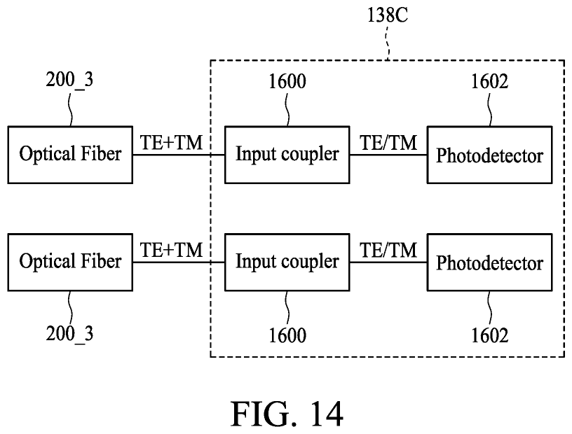

FIG. 14 is a schematic diagram of an optical circuitry of the photoelectric device 10 that serves as the optical receiver in accordance with some embodiments of the present disclosure. Referring to FIG. 14, the optical circuitry 138C includes a plurality of input couplers 1600 and a plurality of photodetectors 1602. The input couplers 1600 receive optical signals from optical fibers 200_3, respectively, and direct the optical signals to the respective photodetectors 1602. The input couplers 1600 may be the two-dimensional grating coupler 1400 shown in FIG. 11. In some embodiments, the photodetector 1602 is configured to determine the intensity and/or the phase of the received optical signal.

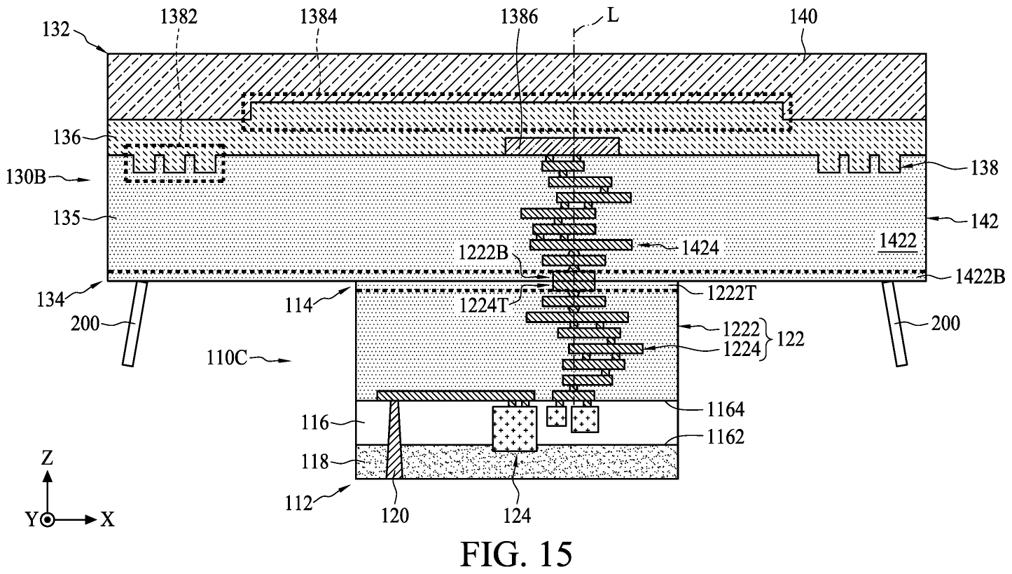

FIG. 15 is a schematic cross-sectional view of an electronic dies 110C and an optical die 130A of the photoelectric device 10 illustrated FIG. 1 The optical die 130A in FIG. 15 is similar to the optical die 130 in FIG. 3, except that, in the optical die 130A of FIG. 15, the optical signals enter and/or exit the photoelectric device 10 through the back side 134 of the optical die 130A. As shown in FIG. 15, the input/output optical couplers 1382 are thus disposed near the back side 134 of the optical die 130A. The electrical circuitry 142 of the optical die 130A and the electronic die 110C shown in FIG. 15 are respectively the same as the electrical circuitry 142 of the optical die 130 and the electronic die 110C shown in FIG. 3, and the detailed descriptions are omitted for the sake of brevity.

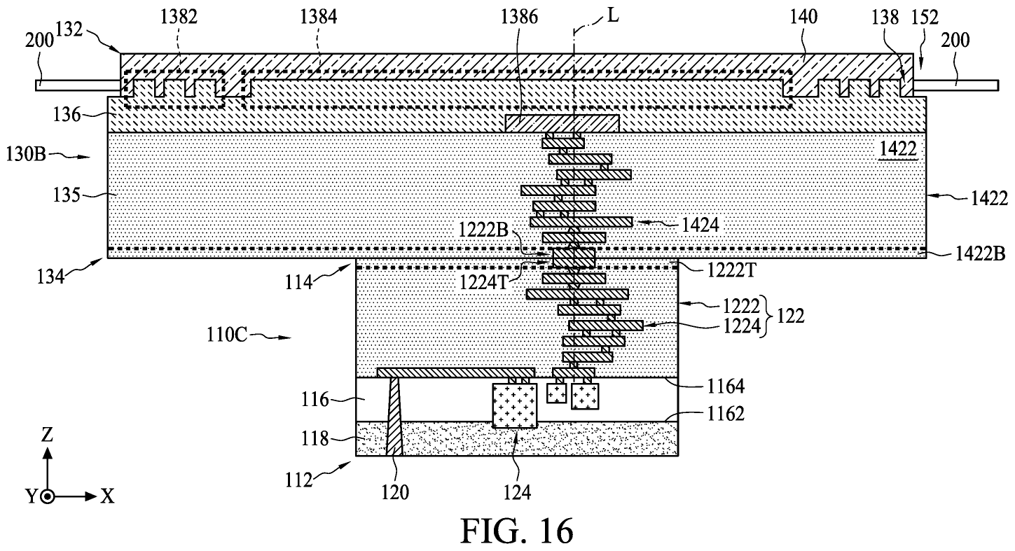

FIG. 16 is a schematic cross-sectional view of an electronic 110C and an optical die 130B of the photoelectric device 10 illustrated in FIG. 1. The optical die 130B in FIG. 16 is similar to the optical die 130 in FIG. 3 in many aspects, and thus descriptions of similar features are not repeated for brevity. The optical die 130B in FIG. 16 is different from the optical die 130 in FIG. 3 in that, in the optical die 130B in FIG. 16, the optical signals enter and/or exit the photoelectric device 10 through sidewalls 135 of the optical die 130B, and the input/output optical couplers 1382 thus include edge couplers. The electronic die 110C shown in FIG. 16 is substantially the same as the electronic die 110C shown in FIG. 3, and the detailed descriptions are omitted for the sake of brevity.

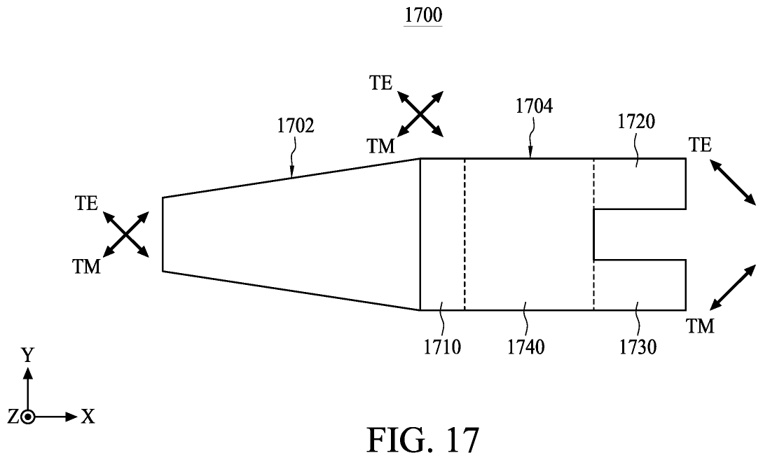

FIG. 17 is a schematic diagram of an input/output optical coupler 1700 in accordance with some embodiments of the present disclosure. Referring to FIG. 17, the input/output optical coupler 1700 includes an edge coupler 1702 and a polarizing beam splitter (PBS) 1704. The edge coupler 1702 is used to transmit optical signals between the optical die 130 and an optical fiber 200. The polarizing beam splitter 1704 is operable to separate polarized optical signals in TE and TM modes from the received optical signals. In some embodiments, the edge coupler 1702 has a tapered shape having a width that increases gradually, wherein the incoming optical signal propagates through the edge coupler 1702 to the polarizing beam splitter 1704. The polarizing beam splitter 1704 includes an input portion 1710 connected to the edge coupler 1702, a first output portion 1720, a second output portion 1730, and a TE-TM mode separation portion 1740 connecting the input portion 1710 to the first and second output portions 1720 and 1730.

The TE-TM mode separation portion 1740 is used to separate the optical signals polarized in the TE mode from the received optical signal, and to provide the optical signals polarized in the TE mode to the first output portion 1720. In addition, the TE-TM mode separation portion 1740 is further used to separate the optical signals polarized in the TM mode from the received optical signal, and to provide the optical signals polarized in the TM mode to the second output portion 1730.

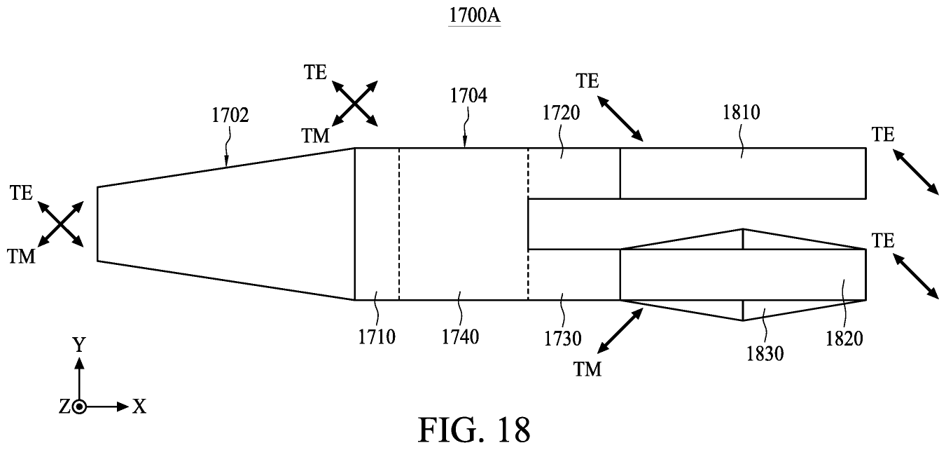

FIG. 18 is a schematic diagram of an input/output optical coupler 1700A in accordance with some embodiments of the present disclosure. The input/output optical coupler 1700A in FIG. 18 is similar to the input/output optical coupler 1700 in FIG. 17, except that the input/output optical coupler 1700A further includes a pair of waveguides 1810 and 1820 and a polarization rotator 1830. In some embodiments, the waveguides 1810 and 1820 are connected to the first and second output ports 1720 and 1730 of the polarizing beam splitter 1704, respectively. The polarization rotator 1830 is optically coupled to the waveguide 1820. The polarization rotator 1830 is configured to rotate optical signals polarized in the TM mode into optical signals polarized in the TE mode, and the input/output optical coupler 1700A thus outputs two branches of optical signals polarized in the TE mode.

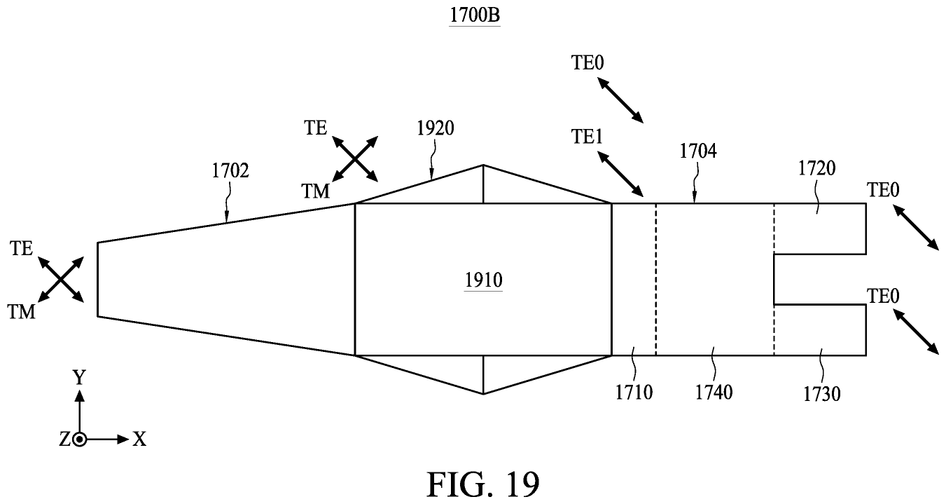

FIG. 19 is a schematic diagram of an input/output optical coupler 1700B in accordance with some embodiments of the present disclosure. The input/output optical coupler 1700B in FIG. 19 is similar to the input/output optical coupler 1700 in FIG. 17, except that the input/output optical coupler 1700B further includes a waveguide 1910 and a polarization rotator 1920. The waveguide 1910 is interposed between the edge coupler 1702 and the polarizing beam splitter 1704. The polarization rotator 1920 is optically coupled to the waveguide 1910. The polarization rotator 1920 is configured to rotate incoming optical signals polarized in the TM mode into optical signals polarized in a first-order TE mode (TE1). Therefore, the input/output optical coupler 1700B outputs two branches of optical signals, wherein one of the branches propagates the optical signal polarized in the TE mode, and another of the branches propagates the optical signal polarized in the TE1 mode.

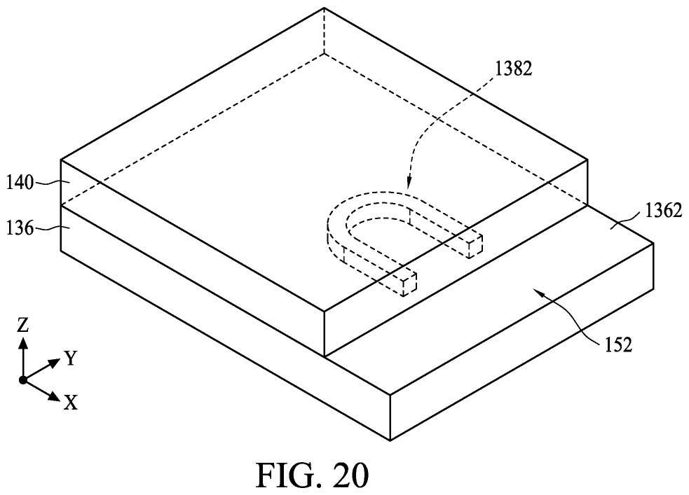

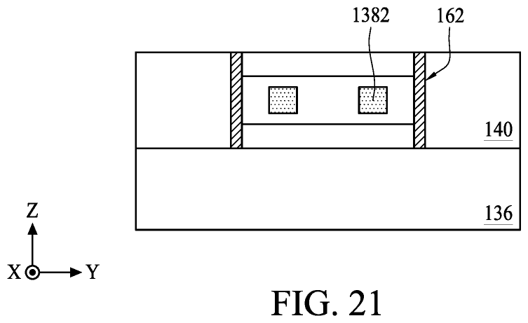

FIG. 20 is a schematic perspective view of a part of the optical die 130, and FIG. 21 is a schematic side view of a part of the optical die 130 in accordance with some embodiments of the present disclosure. Referring to FIGS. 16, 20 and 21, the optical die 130 may further include one or more coupler trenches 152 disposed at edges of the insulating layer 140 and a plurality of alignment marks 162 disposed on sidewalls of the insulating layer 140 exposed through the coupler trenches 152.

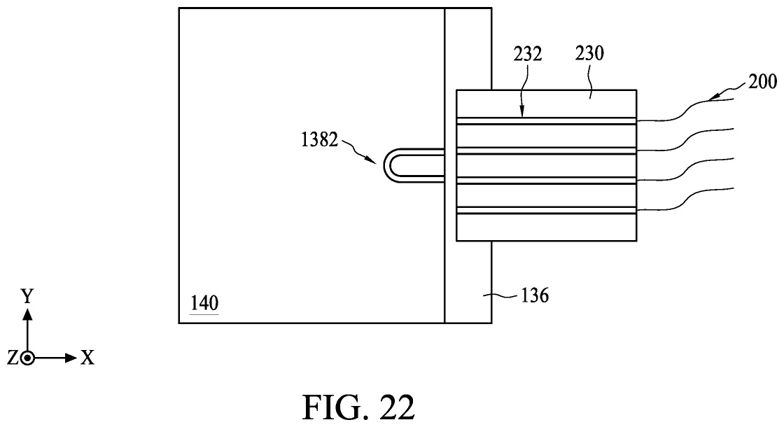

FIG. 22 is a schematic top view of a part of the optical die 130 and the optical fibers 200 in accordance with some embodiments of the present disclosure. Referring to FIG. 22, the optical fibers 200 are positioned at predetermined intervals along the Y direction, for example, by a base 230. The base 230 includes multiple guide holes 232 to receive the optical fibers 200. The base 230 is positioned in the coupler trench 152 and aligned in an area defined by the alignment marks 162. In some embodiments, sidewalls of the base 230 are offset from a top surface 1362 of the semiconductor layer 136 exposed through the coupler trenches 152. Alternatively, a thickness of the base 230 is designed, so that when the base 230 is assembled to the optical die 130, a sidewall of the base 230 is attached to the top surface 1362 of the semiconductor layer 136 exposed through the coupler trenches 152.

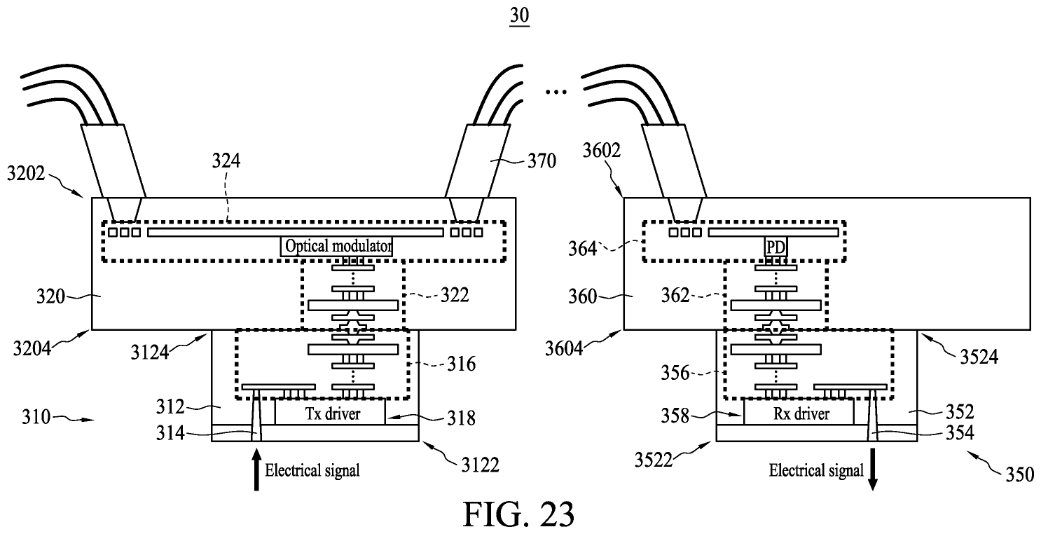

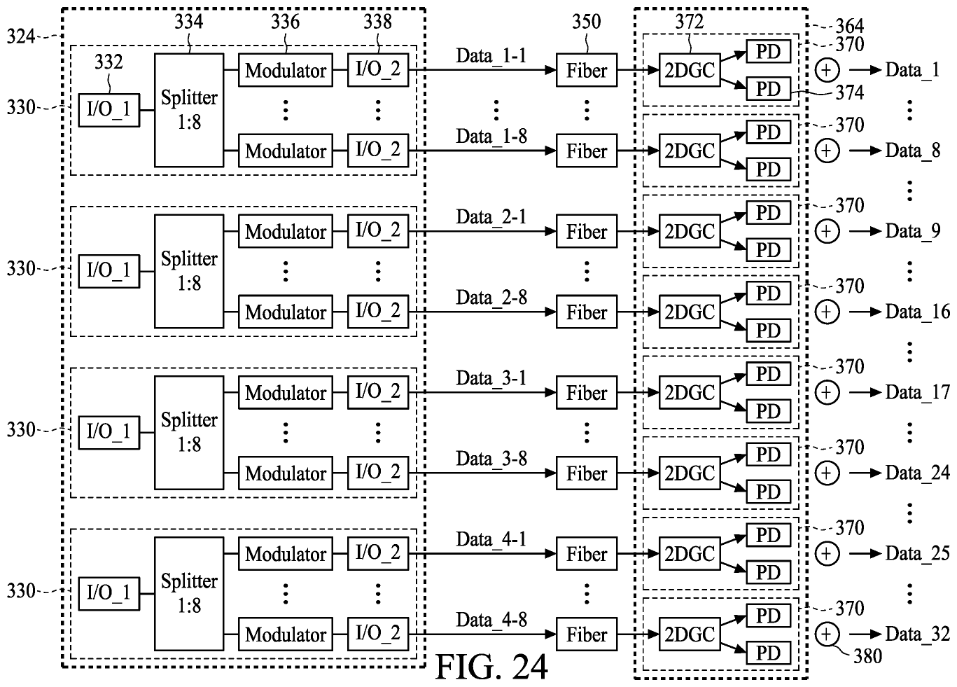

FIG. 23 is a schematic diagram of an optical transceiver 30 in accordance with some embodiments of the present disclosure, and FIG. 24 is a schematic block diagram of a part of the optical transceiver 30 in accordance with some embodiments of the present disclosure. Referring to FIGS. 23 and 24, the optical transceiver 30 includes an optical transmitter 310, an optical receiver 350, and a plurality of optical fibers 370. The optical transmitter 310 communicates to the optical receiver 350 using some of the optical fibers 370. The optical transmitter 310 may have a configuration that is substantially same as that of the optical module 100 shown in FIG. 3. The optical receiver 350 has a configuration similar to that of the optical module 100 shown in FIG. 3 except that the optical receiver 350 includes only one input/output optical coupler.

The optical transmitter 310 includes a first electronic die 312 and a first optical die 320 disposed over the first electronic die 312. The first electronic die 312 has a front side 3122 and a back side 3124 opposite to the front side 3122. The first electronic die 312 includes a conductive pillar 314, an interconnect structure 316, and at least one electronic component 318. The conductive pillar 314 is disposed at the front side 3122. The interconnect structure 316 connects the electronic component 318 to the conductive pillar 314.

The optical die 320 has a front side 3202 and a back side 3204 opposite to the front side 3242. The back side 3204 of optical die 320 is attached to the back side 3124 of the electronic die 310 to form a back-to-back arrangement. The first optical die 320 may include an electrical circuitry 322 and an optical circuitry 324. The electrical circuitry 322 is used to conduct electrical signals for driving the first optical die 320 from the first electronic die 312 to the optical circuitry 324. The optical circuitry 324 is configured to process incoming optical signals.

As shown in FIG. 24, the optical circuitry 324 may include a plurality of transmission modules 330. Each transmission module 330 may include a first I/O coupler (I/O_1) 332, a splitter 334, a plurality of modulators 336, and a plurality of second I/O couplers (I/O_2) 338. The first I/O coupler 332 is used to receive input optical signals. The splitter 334 includes an input port and a plurality of output ports. The input port of the splitter 334 is coupled to one of the first I/O couplers 332, and each output port of the splitter 334 is coupled to one of the modulators 336. The second I/O couplers 338 are coupled to the modulators 336, respectively. In some embodiments, the splitter 334 may have a splitter ratio of 1:8, so that each splitter 334 includes an input port and eight output ports. Accordingly, each transmission module 330 may include eight modulators 336 and eight second I/O couplers 338 to support 8 channels of data streams. As shown in FIG. 24, the optical circuitry 324 including four transmission modules 330 may provide 32 channels of data streams.

Referring back to FIG. 23, the optical receiver 350 includes a second electronic die 352 and a second optical die 360 disposed over the second electronic die 352. The first electronic die 352 has a front side 3522 and a back side 3524 opposite to the front side 3522. The second electronic die 352 includes a conductive pillar 354, an interconnect structure 356, and at least one electronic component 358. The interconnect structure 356 connects the electronic component 358 to the conductive pillar 354.

The optical die 360 has a front side 3602 and a back side 3604 opposite to the front side 3642. The back side 3604 of optical die 360 is attached to the back side 3524 of the electronic die 350 to form a back-to-back arrangement. The second optical die 360 may include an electrical circuitry 362 and an optical circuitry 364. The electrical circuitry 362 is electrically connected to the interconnect structure 356, and the optical circuitry 364 is configured to receive incoming optical signals.

As shown in FIG. 24, the optical circuitry 364 may include a plurality of reception modules 370. Each reception module 370 may include an I/O coupler (2DGC) 372 and a plurality of photodetectors (PD) 374. The I/O couplers 372 are, for example, two-dimensional grating couplers used to separate TE and TM polarized optical signals from the received optical signal. Hence, each I/O coupler 372 may be coupled to two photodetectors 374 for detecting the TE and TM polarized optical signals, respectively. In some embodiments, the TE and TM polarized optical signals from each reception module 370 are added to each other at an adder circuit 380 before being transmitted to the second electronic die 352 shown in FIG. 23. The adder circuit 380 may be a part of the electrical circuitry 362.

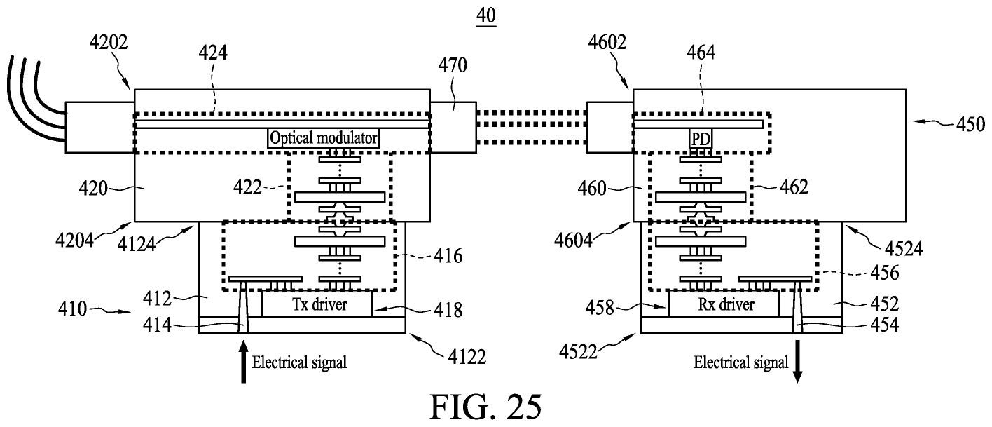

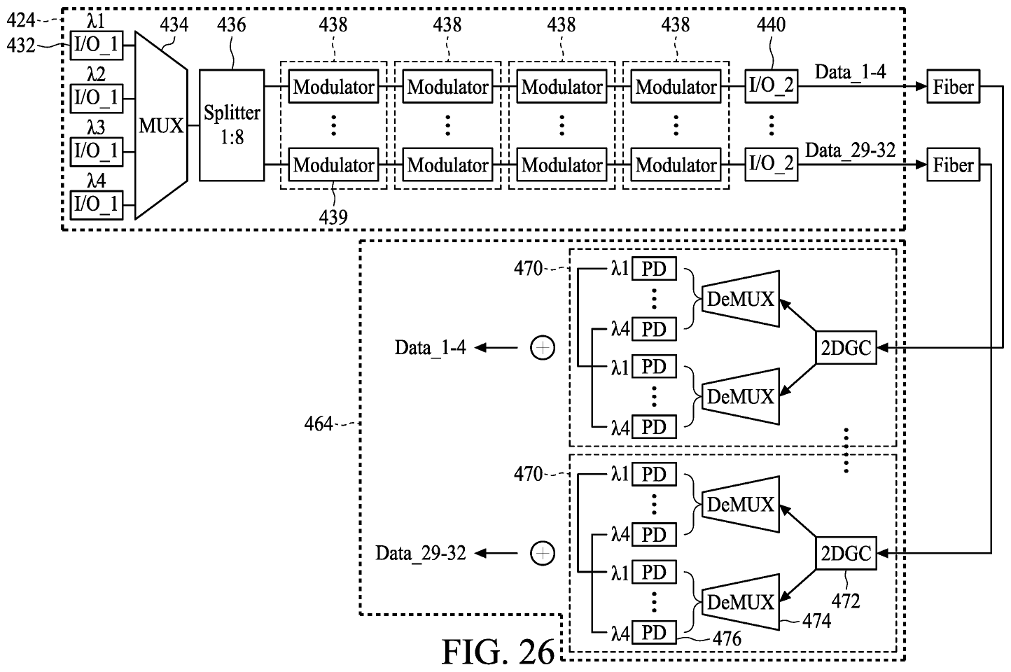

FIG. 25 is a schematic block diagram of an optical transceiver 40 in accordance with some embodiments of the present disclosure, and FIG. 26 is a schematic block diagram of a part of the optical transceiver 40 in accordance with some embodiments of the present disclosure. Referring to FIGS. 25 and 26, the optical transceiver 40 includes an optical transmitter 410, an optical receiver 450, and a plurality of optical fibers 470. The optical fibers 470 connect the optical transmitter 410 to the optical receiver 450. The optical transmitter 410 may have a configuration that is substantially same as a configuration of the optical module 100B shown in FIG. 16. The optical receiver 450 has a configuration that is similar to the configuration of the optical module 100B shown in FIG. 16 except that the optical receiver 450 includes only one input/output optical coupler.

More particularly, the optical transmitter 410 includes a first electronic die 412 and a first optical die 420 disposed over the first electronic die 412. The first electronic die 412 has a front side 4122 and a back side 4124 opposite to the front side 4122. The first electronic die 412 includes a conductive pillar 414, a first interconnect structure 416, and at least one electronic component 418. The first interconnect structure 416 connects the electronic component 418 to the conductive pillar 414.

The optical die 420 has a front side 4202 and a back side 4204 opposite to the front side 4242. The back side 4204 of optical die 420 is bonded to the back side 4124 of the electronic die 410 to form a back-to-back arrangement. The first optical die 420 may include an electrical circuitry 422 and an optical circuitry 424. The optical circuitry 424 is configured to receive incoming optical signals. The electrical circuitry 422 is used to conduct electrical signals from the first electronic die 412 to the optical circuitry 424.

As shown in FIG. 26, the optical circuitry 424 may include a plurality of first I/O couplers (I/O_1) 432, a multiplexer (MUX) 434, a splitter 436, a plurality of modulating units 438, and a plurality of second I/O couplers (I/O_2) 440. The first I/O couplers 432 are used to receive input optical signals having different wavelengths 21 to 24. The multiplexer 434 includes a plurality of input ports and an output port; the input ports of the multiplexer 434 are coupled to the first I/O couplers 432, respectively, and the output port of the multiplexer 434 is coupled to an input port of the splitter 436. The multiplexer 434 receives the optical signals having different wavelengths 21 to 24 and provides a multiplexed optical signal from the output port. The multiplexer 434 functions to increase a capacity of optical communication.

Output ports of the splitter 436 are each coupled to one of the modulating units 438. The optical circuitry 424 may include four modulating units 438 in serial connection. Each of the modulating units 438 may be capable of manipulating polarization, phase, or intensity of the input optical signals. Each modulating unit 438 may include eight modulators 439 having a same configuration, wherein each of the modulators 439 is coupled to one of the output ports of the splitter 436. The optical signals passing through the modulating units 438 are then transmitted to the second I/O couplers 440.

The optical receiver 450 includes a second electronic die 452 and a second optical die 460 disposed over the second electronic die 452. The second electronic die 452 includes a conductive pillar 454, an interconnect structure 456, and at least one electronic component 458. The interconnect structure 456 connects the electronic component 458 to the conductive pillar 454. The second optical die 460 may include an electrical circuitry 462 and an optical circuitry 464. The electrical circuitry 462 is electrically connected to the interconnect structure 456, and the optical circuitry 464 is configured to receive incoming optical signals.

As shown in FIG. 26, the optical circuitry 464 may include a plurality of reception modules 470. Each reception module 470 may include an I/O coupler (2DGC) 472, a pair of optical demultiplexers (DeMUX) 474, and a plurality of photodetectors 476. The I/O couplers 472 are, for example, two-dimensional grating couplers used to separate TE and TM polarized optical signals from the received optical signal. Each of the optical demultiplexers 474 has an input port and a plurality of output ports. Each of the optical demultiplexers 474 receives the TE or TM polarized optical signals via its input port, and then outputs a plurality of demultiplexed optical signals having different wavelengths through different output ports.

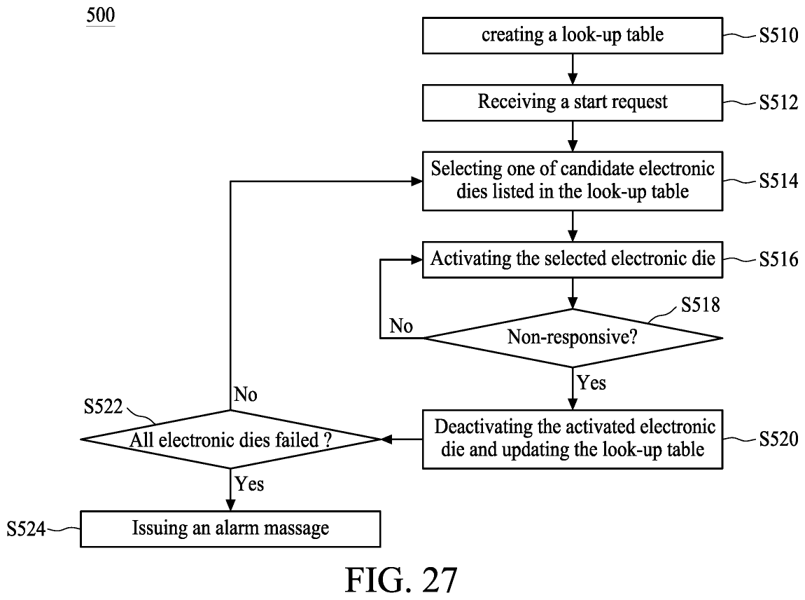

FIG. 27 is a flowchart illustrating exemplary operations of a photoelectric device in accordance with some embodiments of the present disclosure. A method 500 can be performed by processing logic circuitry that can comprise hardware (e.g., circuitry, dedicated logic, programmable logic, microcode, etc.), software (e.g., instructions executed on a processing device), or a combination thereof. For example, various steps in the method 500 may be performed using one or more application programming interfaces operating on one or more processing devices. It should be appreciated that not all steps may be needed to perform the disclosure provided herein. Further, some of the steps may be performed simultaneously, or in an order different from that shown in FIG. 27. The method 500 shall be described with reference to FIG. 1. However, the method 500 is not limited to the example embodiments.

Referring to FIG. 27, the method 500 includes a step S510 of creating a look-up table; a step S512 of receiving a start request; a step S514 of selecting one of candidate electronic dies listed in the look-up table; a step S516 of activating the selected electronic die; a step S518 of determining whether the activated electronic die is non-responsive; a step S520 of deactivating the activated electronic die and dies and updating the look-up table if the activated electronic die is non-responsive; a step S522 of determining whether all electronic dies have failed; and a step S524 of issuing an alarm signal if all electronic dies have failed.

The following describes the method 500 using the above-mentioned photoelectric device 10. In particular, the photoelectric device 10 includes an optical die 130 and a plurality of electronic dies 110C including a communication drive circuitry. The communication drive circuitry is configured to drive the optical die 130 to generate, process, or receive optical signals.

Referring to FIGS. 1 and 27, the method 500 can begin at step S510, in which a look-up table is created. The look-up table, which is to be used subsequently, may include information of all electronic dies 110C in the photoelectric device 10. For example, the look-up table may include information that reflects a status of each electronic die 110C, i.e., normal or abnormal (wherein an electronic die 110C with an abnormal status is considered a failed die). The information may further include historical process performance, historical (parameter) data collected from periodic tests, or the like associated with each electronic die 110C. In some embodiments, the look-up table includes an indication of whether an electronic die 110C is functional or not. The electronic die 110C that is functional may allow the photoelectric device 10 to operate normally; such electronic die 110C is thus extracted as a candidate electronic die. The electronic die 110C that is non-functional is considered a failed die.

The method 500 then proceeds to step 512, in which a start request is received. The start request may be issued by an operator to start the photoelectric device 10. In response to the start request, one of candidate electronic dies 110C listed in the look-up table is selected (step S514). In some embodiments, the electronic die 110C is selected randomly from the candidate electronic dies 110C. In alternative embodiments, the method 500 may evaluate the candidate electronic dies 110C in some defined order (e.g., beginning with electronic dies 110C that have been selected and subsequently proceeding to electronic dies 110C that have not been selected).

The method 500 continues with step S516, in which the selected electronic die 110C is activated to perform operations for driving the optical die 130. The operations include, for example, providing a driving signal to the optical die 130 and monitoring an operation status of the optical die 130. In some embodiments, the non-selected candidate electronic dies 110C are deactivated to prevent operation error or device malfunction.

Subsequently, the method 500 proceeds to a determination step S518. In step S518, it is determined whether the activated electronic die 110C is non-responsive. If the determination is negative (i.e., if the activated electronic die 110C is responsive), the method 500 returns to step S516, and the selected electronic die 110C remains activated. If, on the other hand, the determination is positive (i.e., if the activated electronic die 110C is non-responsive), the activated electronic die 110C is considered to be in an abnormal state, and the method 500 proceeds to step S520. In step S520, the activated electronic die 110C is deactivated, and the look-up table is updated to reflect the abnormal operation of the deactivated electronic die 110C.

After updating the look-up table, the method 500 proceeds to a determination step S522. In step S522, it is determined whether all electronic dies 110C have failed. If the determination is negative, the method returns to step S514, in which another candidate electronic die 110C is selected from the look-up table. If the determination in step S522 is positive (i.e., if all electronic dies 110C have failed), then no candidate electronic die 130C is available, and the method 500 proceeds to step S524, in which an alarm signal is issued to inform the operator that the photoelectric device 10 has expired.

In accordance with some embodiments of the present disclosure, a photoelectric device is provided. The photoelectric device include a first die and a second die. The first die has a first back side and a first front side opposite to the first back side. The second die is disposed over the first die. The second die has a second back side and a second front side opposite to the second back side and bonded to the first front side. The second die includes an optical circuitry and an electrical circuitry. The optical circuitry is configured to generate or process a first optical signal. The electrical circuitry is electrically coupled to the first die, and is configured to control an operation of the optical circuitry by a first electrical signal inputted into the first die or to provide a second electrical signal to the first die in response to the first optical signal.

In accordance with some embodiments of the present disclosure, an optical transceiver is provided. The optical transceiver includes an optical transmitter, an optical receiver, and an optical fiber. The optical transmitter includes a first electronic die and a first optical die. The first electronic die has a first back side and a first front side opposite to the first back side. The first optical die is disposed over the first electronic die. The first optical die has a second front side and a second back side opposite to the second front side. The first optical die includes an optical circuitry configured to generate or process a first optical signal and an electrical circuitry electrically coupled to the first electronic die. The electrical circuitry is configured to control an operation of the optical circuitry by a first electrical signal inputted into the first electronic die. The optical fiber is configured to transmit the first optical signal to the optical receiver.

In accordance with some embodiments of the present disclosure, a method of operating a photoelectric device is provided. The photoelectric device includes a plurality of electronic dies having a same configuration and an optical die disposed over the electronic dies. The method includes steps of receiving a start request; activating one of the electronic dies; determining whether the activated electronic die is non-responsive; in response to a determination that the activated electronic die is non-responsive, deactivating the activating electronic die; and activating another electronic die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photoelectric device, comprising:
a first die including a first back side and a first front side opposite to the first back side; and
a second die disposed over the first die, and including a second front side and a second back side opposite to the second front side and bonded to the first back side, wherein the second die comprises:
an optical circuitry configured to generate or process a first optical signal; and
an electrical circuitry electrically coupled to the first die, configured to control an operation of the optical circuitry by a first electrical signal inputted into the first die or to generate a second electrical signal and provide the second electrical signal to the first die in response to the first optical signal.

2. The photoelectric device of claim 1, wherein the first die comprises:
a substrate;
a dielectric layer disposed on the substrate and at the first front side of the first die;
an electronic component disposed in or on the substrate;
a conductive pillar extending through the dielectric layer and to the substrate; and
a first interconnect structure disposed on the substrate and at the first back side of the first die, wherein the first interconnect structure connects the conductive pillar to the electronic component,
wherein the conductive pillar is utilized to receive the first electrical signal from an external circuitry or to transmit the second electrical signal to the external circuitry.

3. The photoelectric device of claim 2, wherein:
the electronic component is disposed at the first front side of the first die and is separated laterally from the conductive pillar;
the first interconnect structure comprises a plurality of first conductive features; and
the electronic component is overlapped by the first conductive features from a top-view perspective.

4. The photoelectric device of claim 2, wherein the second die further comprises:
a semiconductor layer, wherein the optical circuitry is disposed therein or thereover; and
a second interconnect structure disposed on the semiconductor layer and at the second back side of the second die,
wherein the second interconnect structure is physically and electrically coupled to the first interconnect structure.

5. The photoelectric device of claim 4, wherein the optical circuitry comprises an optical feature operable to generate or process the first optical signal, the optical feature is disposed in or on the semiconductor layer and electrically coupled to the electrical circuitry, and the optical feature overlaps the electronic component from a top-view perspective.

6. The photoelectric device of claim 1, wherein the second die is hybrid-bonded to the first die.

7. The photoelectric device of claim 1, further comprising a dummy die laterally separated from the first die and bonded to the second die.

8. The photoelectric device of claim 1, wherein the first optical signal enters or exits the second die through the second front side, the first electrical signal is inputted into the first die through the first front side, and the second electrical signal exits the first die through the first front side.

9. An optical transceiver, comprising:
an optical transmitter comprising:
a first electronic die including a first back side and a first front side opposite to the first back side; and
a first optical die disposed over the first electronic die, and including a second front side and a second back side opposite to the second front side, wherein the first optical die comprises:
an optical circuitry configured to generate or process a first optical signal; and
an electrical circuitry electrically coupled to the first electronic die, wherein the electrical circuitry is configured to control an operation of the optical circuitry by a first electrical signal inputted into the first electronic die;
an optical receiver; and
an optical fiber configured to transmit the first optical signal to the optical receiver.

10. The optical transceiver of claim 9, wherein the optical fiber is attached to the second front side or the second back side of the first optical die.

11. The optical transceiver of claim 10, wherein the first optical die further comprises:
a semiconductor layer, wherein the optical circuitry is disposed therein or thereover;
an insulating layer disposed on the semiconductor layer and at the second front side of the first optical die, wherein the insulating layer is used to surround and cover the optical circuitry; and
a coupler recess disposed in the insulating layer, wherein the coupler recess overlaps a part of optical circuitry from a top-view perspective,
wherein the optical fiber is disposed on or in the coupler recess.

12. The optical transceiver of claim 11, wherein the first optical die further comprises an alignment mark disposed in or on the insulating layer and exposed through the coupler recess.

13. The optical transceiver of claim 11, wherein the optical circuitry comprises a two-dimensional grating coupler overlapped by the coupler recess from the top-view perspective.

14. The optical transceiver of claim 10, wherein the first optical die further comprises:
a semiconductor layer, wherein the optical circuitry is disposed therein or thereover;
an insulating layer disposed on the semiconductor layer and at the second front side of the first optical die, wherein the insulating layer surrounds and covers the optical circuitry; and
a coupler trench penetrating through the insulating layer at an edge of the semiconductor layer,
wherein a portion of the optical fiber is disposed in the coupler trench.

15. The optical transceiver of claim 14, wherein the first optical die further comprises an alignment mark disposed on a sidewall exposed through the coupler trench.

16. The optical transceiver of claim 14, wherein the optical circuitry comprises an edge coupler and a polarizing beam splitter connected to the edge coupler.

17. The optical transceiver of claim 16, wherein the optical circuitry further comprises a polarization rotator interposed between the edge coupler and the polarizing beam splitter.

18. A method of operating a photoelectric device, the photoelectric device comprising a plurality of electronic dies and an optical die disposed over the plurality of electronic dies, the method comprising:
receiving a start request;
activating one of the plurality of electronic dies;
determining whether the activated one of the plurality of electronic dies is non-responsive; and
deactivating the activated one of the plurality of electronic dies or
activating another one of the plurality of electronic dies based on the determination.

19. The method of claim 18, further comprising:
issuing an alarm signal if all of the plurality of electronic dies are non-responsive.

20. The method of claim 19, further comprising:
updating a look-up table comprising information reflecting a current status of each of the plurality of electronic dies.
